(19) United States
(12) Patent Application Publication
(10) Pub. No.: US 2025/0364512 A1
(43) Pub. Date: Nov. 27, 2025

(54) STACKING OF OPTICAL STRUCTURES USING CONDUCTIVE MATERIALS AND REFLECTORS

(71) Applicant: ADEIA SEMICONDUCTOR BONDING TECHNOLOGIES INC., San Jose, CA (US)

(72) Inventors: Gaius Gillman Fountain, JR., Youngsville, NC (US); Belgacem Haba, Saratoga, CA (US); Rajesh Katkar, Milpitas, CA (US); Oliver Zhao, Sunnyvale, CA (US)

(21) Appl. No.: 18/791,184

(22) Filed: Jul. 31, 2024

Related U.S. Application Data
(60) Provisional application No. 63/650,786, filed on May 22, 2024.

(51) Int. Cl. H01L 25/16; H01L 21/48; H01L 23/498; H01L 33/42; H01L 33/60; H01L 33/62

(52) U.S. Cl. CPC H01L 25/167; H01L 21/4857; H01L 23/49822; H01L 23/49838; H01L 25/162; H10H 20/833; H10H 20/856; H10H 20/857

(57) ABSTRACT

A structure includes at least one first optical emitter at or below an outer surface and to emit a first light in a first direction away from the outer surface. The structure further includes at least one optically transparent first layer beneath the at least one first optical emitter and at least one electrically conductive and optically reflective second layer in electrical communication with the at least one first optical emitter. The at least one electrically conductive and optically reflective second layer to receive at least some of the first light propagating in the first direction from the at least one first optical emitter through the at least one optically transparent first layer and to at least twice reflect at least a portion of the received first light to propagate in a second direction towards and through the outer surface. The second direction is substantially different from the first direction.

### BACKGROUND

### Field

The field relates to systems and methods for wafer-to-wafer, die-to-die, and/or die-to-wafer hybrid bonding for semiconductor devices and optoelectronic devices.

### Description of the Related Art

Semiconductor elements, such as semiconductor wafers or integrated device dies, can be stacked and directly bonded to one another without an adhesive, thereby forming a bonded structure. Nonconductive (e.g., dielectric; semiconductor) surfaces can be made extremely smooth and treated to enhance direct, covalent bonding, even at room temperature and without application of pressure beyond contact. In some hybrid bonded structures, nonconductive field regions of the elements can be directly bonded to one another, and corresponding conductive contact structures can be directly bonded to one another.

For example, a semiconductor element can be mounted to a carrier, such as a package substrate, an interposer, a reconstituted wafer or element, a flat panel, a glass, etc. A semiconductor element can be stacked on top of the semiconductor element (e.g., a first integrated device die can be stacked on a second integrated device die). Each of the semiconductor elements can have conductive pads for mechanically and electrically bonding the semiconductor elements to one another with the conductive pads mechanically and electrically bonded to one another.

### SUMMARY

Certain implementations described herein provide a structure comprising an outer surface and at least one first optical emitter at or below the outer surface. The at least one first optical emitter to emit a first light in a first direction away from the outer surface. The structure further comprises at least one optically transparent first layer beneath the at least one first optical emitter. The structure further comprises at least one electrically conductive and optically reflective second layer in electrical communication with the at least one first optical emitter, the at least one electrically conductive and optically reflective second layer to receive at least some of the first light propagating in the first direction from the at least one first optical emitter through the at least one optically transparent first layer and to at least twice reflect at least a portion of the received first light to propagate in a second direction towards and through the outer surface. The second direction is substantially different from the first direction.

Certain implementations described herein provide a method comprising providing a first substrate comprising a first wafer comprising a first semiconductor material and having an outer surface and forming grooves extending along the outer surface. The method further comprises forming a first oxide layer over the outer surface and the grooves. The method further comprises conformally depositing an electrically conductive and optically reflective first reflecting layer over the first oxide layer at least within the grooves and removing portions of the first reflecting layer and the first oxide layer outside the grooves. The method further comprises depositing and planarizing a second oxide layer over the first reflecting layer within the grooves and over the outer surface. The method further comprises forming electrically conductive and optically transparent first contacts embedded within the second oxide layer and in electrical communication with the first reflecting layer. The method further comprises providing a second substrate comprising a third oxide layer at an outer surface of the second substrate and second contacts embedded in the third oxide layer. The method further comprises directly bonding the second substrate to the first substrate.

Certain implementations described herein provide a structure comprising a first optical element. The first optical element comprises at least one first optical emitter and a bonding layer over the at least one first optical emitter. The bonding layer comprises a first insulating layer and a first electrically conductive and optically transparent contact at least partially embedded in the first insulating layer, the at least one first optical emitter to emit a first light in a first direction. The first optical element further comprises a first mirror structure comprising an optically reflective layer, a second insulating layer over the optically reflective layer, and a second electrically conductive and optically transparent contact at least partially embedded in the second insulating layer. The first insulating layer is directly bonded to the second insulating layer, and the first electrically conductive and optically transparent contact is directly bonded to the second electrically conductive and optically transparent contact.

Certain implementations described herein provide a structure comprising an outer surface, a first optical element, and a second optical element. The first optical element is at or below the outer surface and includes a first mirror structure and at least one first optical emitter to emit a first light in a first direction away from the outer surface. The first mirror structure is arranged to reflect at least some of the first light in a second direction substantially different from the first direction. The second optical element is bonded to the first optical element, and includes a second mirror structure and at least one second optical emitter to emit a second light in a third direction away from the outer surface. The second mirror structure is arranged to reflect at least some of the second light in a fourth direction substantially different from the third direction. The reflected first light propagates along a first optical channel through the outer surface and the reflected second light propagates along a second optical channel through the outer surface, the first and second optical channels laterally spaced from one another along a direction transverse to the first direction.

### BRIEF DESCRIPTION OF THE DRAWINGS

Specific implementations will now be described with reference to the following drawings, which are provided by way of example, and not limitation.

FIG. 1A is a schematic cross-sectional side view of two elements prior to bonding in accordance with certain implementations described herein.

FIG. 1B is a schematic cross-sectional side view of the two elements of FIG. 1A after bonding in accordance with certain implementations described herein.

FIGS. 2A-2C schematically illustrate cross-sectional views of various example structures in accordance with certain implementations described herein.

FIG. 3 is a flow diagram of an example method 300 for fabricating a structure utilizing at least one oxide material in accordance with certain implementations described herein.

FIGS. 4A-4M schematically illustrate cross-sectional views of various example structures that are fabricated at stages of the method in accordance with certain implementations described herein.

FIGS. 5A and 5B schematically illustrate side views of two example structures in accordance with certain implementations described herein.

FIG. 6 schematically illustrates a top view of the outer surface through which the first, second, and third light are transmitted in accordance with certain implementations described herein.

### DETAILED DESCRIPTION

Various implementations disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some implementations, nonconductive bonding layers can be blanket deposited over the base substrate portions without being patterned with conductive features (e.g., without pads). In other implementations, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various implementations, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some implementations, the dielectric materials at the bonding surface do not comprise polymer materials, such as epoxy (e.g., epoxy adhesives, cured epoxies, or epoxy composites such as FR-4 materials), resin or molding materials.

In other implementations, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other implementations, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in implementations that utilize a nitrogen plasma for activation, a nitrogen concentration peak can be formed at the bond interface. In some implementations, the nitrogen concentration peak may be detectable using secondary ion mass spectroscopy (SIMS) techniques. In various implementations, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In implementations that utilize an oxygen plasma for activation, an oxygen concentration peak can be formed at the bond interface between non-conductive bonding surfaces. In some implementations, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

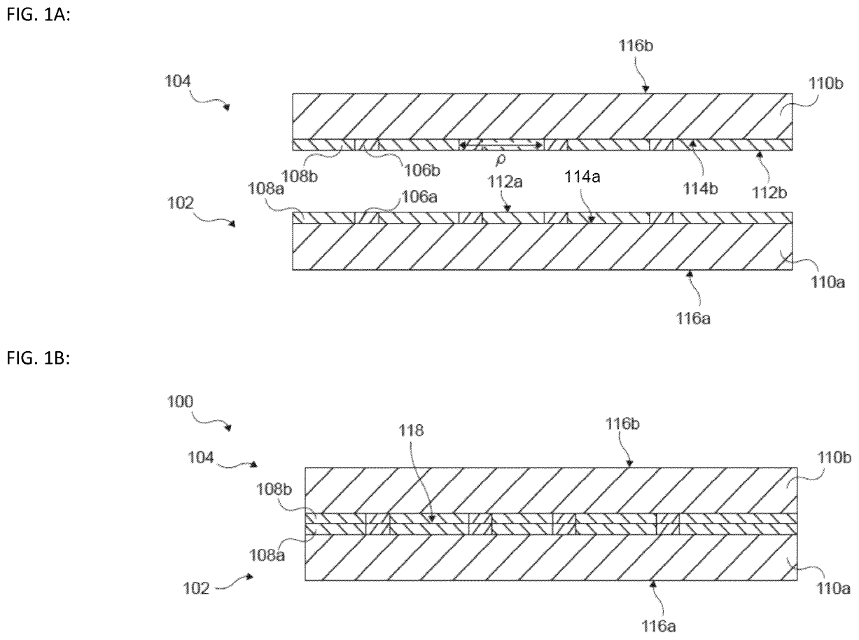

FIGS. 1A and 1B schematically illustrate cross-sectional side views of first and second elements 102, 104 prior to and after, respectively, a process for forming a directly bonded structure, and more particularly a hybrid bonded structure, according to some implementations. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated implementation are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some implementations, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other implementations, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some implementations, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some implementations, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other implementations, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other implementations, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other implementations such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The implementations disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some implementations, a laterally stacked additional element may be smaller than the second element. In some implementations, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some implementations, one or both of the surfaces 112a, 112b can be terminated with a species after activation or during activation (e.g., during the plasma and/or etch processes). Without being limited by theory, in some implementations, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some implementations, the activation and termination are provided in the same step, e.g., a plasma to activate and terminate the surface(s) 112a, 112b. In other implementations, one or both of the bonding surfaces 112a, 112b can be terminated in a separate treatment to provide the additional species for direct bonding. In various implementations, the terminating species can comprise nitrogen. For example, in some implementations, the bonding surface(s) 112a, 112b can be exposed to a nitrogen-containing plasma. Other terminating species can be suitable for improving bonding energy, depending upon the materials of the bonding surfaces 112a, 112b. Further, in some implementations, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some implementations, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some implementations, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some implementations, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some implementations, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding implementations, opposing conductive materials are joined without heating above the conductive materials' melting temperature, such that bonds can form with lower anneal temperatures compared to soldering or thermocompression bonding.

In various implementations, the conductive features 106a, 106b can comprise discrete pads, contacts, electrodes, or traces at least partially embedded in the non-conductive field regions of the bonding layers 108a, 108b. In some implementations, the conductive features 106a, 106b can comprise exposed contact surfaces of TSVs (e.g., through silicon vias).

As noted above, in some implementations, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some implementations, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various implementations, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated implementation, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some implementations, the materials of the conductive features 106a, 106b of opposite elements 102, 104 can interdiffuse during the annealing process. In some implementations, metal grains grow into each other across the bond interface 118. In some implementations, the metal is or includes copper, which can have grains oriented along the 111 crystal plane for improved copper diffusion across the bond interface 118. In some implementations, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some implementations, a barrier layer may be provided under and/or laterally surrounding the conductive features 106a and 106b (e.g., which may include copper). In other implementations, however, there may be no barrier layer under the conductive features 106a and 106b.

Certain implementations disclosed herein relate to optoelectronic devices that include directly bonded contacts comprising optically transparent or optically semi-transparent electrically conducting material (referred to herein collectively as transparent conductors or TCs) instead of conventional metal direct bonded contacts. For example, the optoelectronic devices can include optical elements or devices (e.g., photodiodes; light emitting diodes (LEDs)); quantum dot light emitting diodes (QLEDs); microLEDs, lasers; vertical-cavity surface-emitting lasers (VCSELs); transparency control pixels; liquid crystal pixels; adaptive optics; solar cells; waveguides; spatial light modulators; diode lasers; electrochromic devices) that are stacked on or bonded to one another to form a bonded structure. The TCs on separate substrates can be planarized and the planarized surfaces of the substrates can be placed in contact with one another, as described herein, to form the bonded structures.

In certain implementations, the optoelectronic devices described herein are configured to be used in various contexts which are area-limited (e.g., displays for virtual reality (VR), augmented reality (AR) applications, mixed reality (MR); multijunction solar cells) or other designs comprising an optoelectronic (e.g., electro-optical) element within a stack of other optical elements, beneficially utilizing the TCs for providing electrical connection between electrical elements while not appreciably blocking light.

As used herein, the term “optically transparent” includes but is not limited to optically translucent, optically semi-transparent, and/or having an optical transmittance of at least 50% (e.g., at least 60%; at least 75%; at least 88%; greater than or equal to 95%) at optical wavelengths in a predetermined range. For example, the predetermined range for optically transparent components (e.g., elements; substrates; layers; devices; features) can be visible wavelengths (e.g., 390 nanometers to 750 nanometers; 400 nanometers to 700 nanometers), ultraviolet wavelengths (e.g., 100 nanometers to 400 nanometers), infrared wavelengths (e.g., 800 nanometers to 1 millimeter), and/or short-wave infrared (SWIR) wavelengths (e.g., 1400 nanometers to 3000 nanometers).

As described herein, some electrically conductive oxides (e.g., indium tin oxide or ITO) or nitrides have the ability to self-bond at modest temperatures (e.g., in a range of 75° C. to 400° C.; in a range of 120° C. to 300° C.; in a range of 150° C. to 300° C.). In certain implementations, use of electrically conductive oxide or nitride layers can simplify processes for bonding (e.g., blanket wafer and hybrid bonding surfaces) by omitting one or more other processing steps (e.g., planarization and/or surface activation). For example, the electrically conductive oxide or nitride layers can be self-leveled if planarized before patterning. In conjunction with certain layout structures, such electrically conductive oxide or nitride layers can be used to bond multiple input/output components with a single material interface. For example, ITO can be used to bond two substrates without a surface activation step, and in certain implementations, without a surface planarization (e.g., chemical-mechanical polishing or CMP) step. The electrically conductive oxide or nitride layers can also allow bonding at modest temperatures (e.g., less than 300° C.) and can be used for surface mounting. In view of the electrical conductivity, such layers can provide electromagnetic shielding for other components of the electronic packages. In addition, because certain such materials are substantially optically transparent, they can be used for bonding optoelectronic applications, as well as in other structures where photon transmission is not a factor.

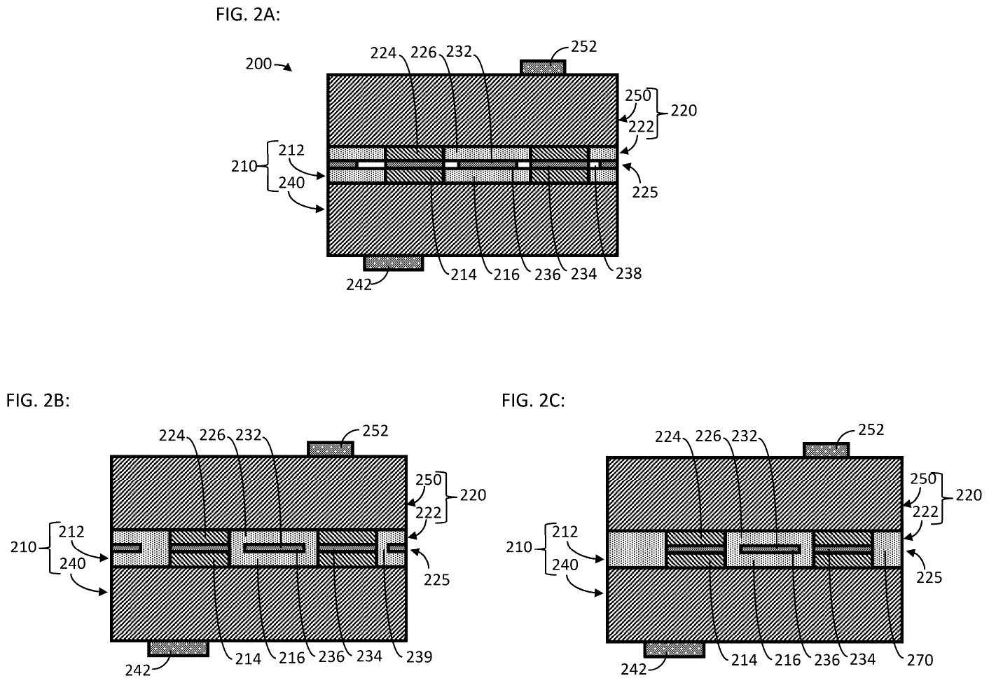

FIGS. 2A-2C schematically illustrate cross-sectional views of various example structures 200 in accordance with certain implementations described herein. The example structures 200 of FIGS. 2A-2C comprise a first substrate 210 (e.g., first element 102) comprising a first layer 212 having at least one electrically conductive first portion 214 (e.g., conductive feature 106a) and at least one electrically insulative second portion 216. The structures 200 further comprise a second substrate 220 (e.g., second element 104) comprising a second layer 222 having at least one electrically conductive third portion 224 (e.g., conductive feature 106b) and at least one electrically insulative fourth portion 226. The structures 200 further comprise an interface layer 225 between the first layer 212 and the second layer 222 (e.g., formed by direct bonding of two opposing layers of at least one oxide material 232 that is electrically conductive and optically transparent). The interface layer 225 comprises the at least one oxide material 232. The at least one oxide material 232 comprises at least one first region 234 between and in electrical communication with the at least one electrically conductive first portion 214 and the at least one electrically conductive third portion 224. The at least one oxide material 232 further comprises at least one second region 236 between the at least one electrically insulative second portion 216 and the at least one electrically insulative fourth portion 226.

In certain implementations, the first substrate 210 comprises at least one first device 240 and the second substrate 220 comprises at least one second device 250. The at least one first device 240 and/or the at least one second device 250 can be optically transparent (e.g., optoelectronic device; optoelectronic element; electro-optical element; solar cell) or can be optically non-transparent (e.g., opaque). The at least one first device 240 and/or the at least one second device 250 can further comprise electrical conduits (e.g., optically transparent; non-optically transparent). In certain implementations, the first substrate 210 comprises at least one electrical contact 242 (e.g., a large lateral area contact on a backside 116a of the corresponding device portion 110a) in electrical communication with the at least one first device 240 and the second substrate 220 comprises at least one electrical contact 252 (e.g., on a backside 116b of the corresponding device portion 110b) in electrical communication with the at least one second device 250. The electrical contacts 242, 252 can be configured to transmit electrical signals to and/or from the first and/or second devices 240, 250. Example materials for the electrical contacts 242, 252 include but are not limited to copper or copper alloys, although other metals and alloys may be suitable. In addition, the electrical contacts 242, 252 can comprise additional electrically conductive layers between the copper and the corresponding at least one first and/or second device 240, 250. In certain implementations, at least one of the electrical contacts 242, 252 comprises an electro-optical (EO) contact comprising a transparent and electrically conductive material (e.g., an electrically conductive oxide material as disclosed herein) that is in electrical and optical communication with the at least one first device 240 and the at least one second device 250, respectively, to transmit electrical and optical signals to and/or from the first and/or second devices 240, 250.

In certain implementations, the at least one electrically conductive first portion 214 and/or the at least one electrically conductive third portion 224 comprises at least one electrically conductive material, examples of which include, but are not limited to: copper; tungsten; cobalt; doped and undoped metal oxides; aluminum zinc oxide (AZO); indium tin oxide (ITO, In₂O₃); zinc oxide (ZnO); zinc tin oxide (ZnSnO₃, Zn₂SnO₄); indium-doped zinc oxide (IZO); indium oxide; cadmium tin oxide (Cd₂SO₄); tin oxide (SnO₂); titanium dioxide (TiO₂); niobium-doped titanium dioxide (Nb—TiO₂); titanium nitride (TiN); tin nitride (Sn₃N₄); other metal nitrides (e.g., A₃N₂ where A=Mg, Zn, Sn); transition metal nitrides comprising a IIIB, IVB, or VB transition metal. In certain implementations, the first and/or third portions 214, 224 are optically transparent, while in certain other implementations, the first and/or third portions 214, 224 are optically non-transparent (e.g., opaque). Each of the first portion 214 and/or the third portion 224 can comprise a single layer or multiple layers. The first and third portions 214, 224 can comprise the same electrically conductive material or can comprise different electrically conductive materials (e.g., materials having different elemental constituents and/or different stoichiometries). The electrically conductive materials of the first and/or third portions 214, 224 can be different from the at least one oxide material 232, and the bonding of the first and/or third portions 214, 224 with the interface layer 225 can comprise hybrid bonding.

In certain implementations, the at least one electrically insulative second portion 216 and/or the at least one electrically insulative fourth portion 226 comprises at least one dielectric material (e.g., an inorganic dielectric material), examples of which include, but are not limited to: semiconductor oxides; semiconductor nitrides; silicon oxide (SiO₂); silicon nitride (SiNₓ, Si₃N₄); silicon oxycarbonitride (SiOₓN_{y}C_{z}); titanium oxide. In certain implementations, the second and/or fourth portions 216, 226 are optically transparent, while in certain other implementations, the second and/or fourth portions 216, 226 are optically non-transparent (e.g., opaque). Each of the second portion 216 and/or the fourth portion 226 can comprise a single layer or multiple layers. The second and fourth portions 216, 226 can comprise the same dielectric material or can comprise different dielectric materials (e.g., materials having different elemental constituents and/or different stoichiometries). The dielectric materials of the second and/or fourth portions 216, 226 are different from the at least one oxide material 232, and the bonding of the second and/or fourth portions 216, 226 with the interface layer 225 can comprise hybrid bonding.

In certain implementations, the at least one oxide material 232 is selected from the group consisting of: indium tin oxide (ITO); zinc oxide (ZnO); indium-doped zinc oxide (IZO); tin oxide (SnO₂). In certain implementations, the at least one oxide material 232 is optically transparent, while in certain other implementations, the at least one oxide material 232 is optically non-transparent (e.g., opaque). As described herein, the at least one oxide material 232 can comprise a first oxide material 232a on the first layer 212 and a second oxide material 232b on the second layer 222, and the interface layer 225 can be formed by directly bonding the first oxide material 232a to the second oxide material 232b. In certain implementations, the interface layer 225 has a thickness in a range of 5 nanometers to 3 microns. In certain implementations, the resistivity of the at least one oxide material 232 is in a range less than 500×10⁻⁶ Ω-cm (e.g., 200×10⁻⁶ Ω-cm to 40×10⁻⁶ Ω-cm; 500×10⁻⁶ Ω-cm to 20×10⁻⁶ Ω-cm; in a range less than 120×10⁻⁶ Ωcm). In certain implementations, the optical transmission of the at least one oxide material 232 within the wavelength range of interest is greater than 40% (e.g., greater than 60%; greater than 80%).

In certain implementations, the interface layer 225 is patterned such that the at least one first region 234 is electrically isolated from the at least one second region 236. For example, as schematically illustrated by FIG. 2A, the structure 200 can further comprise gaps 238 between the at least one first region 234 and the at least one second region 236. In certain implementations, the gaps 238 comprise gas (e.g., air; nitrogen) and can be at atmospheric pressure, less than atmospheric pressure (e.g., vacuum pressure), or greater than atmospheric pressure. As schematically illustrated by FIG. 2A, the at least one oxide material 232 is not embedded within the at least one electrically insulative second portion 216 and/or the at least one electrically insulative fourth portion 226.

For another example, as schematically illustrated by FIG. 2B, the interface layer 225 can comprise at least one solid dielectric material 239 (e.g., silicon oxycarbonitride or SiOₓN_{y}C_{z}) between the at least one first region 234 and the at least one second region 236. The at least one solid dielectric material 239 can be different from the materials of the at least one electrically insulative second portion 216 and/or the at least one electrically insulative fourth portion 226, or the at least one solid dielectric material 239 can be the same as the material of the at least one electrically insulative second portion 216 and/or the at least one electrically insulative fourth portion 226. As schematically illustrated by FIG. 2B, the at least one oxide material 232 is at least partially embedded (e.g., fully embedded) within the at least one electrically insulative second portion 216 and/or the at least one electrically insulative fourth portion 226.

In certain implementations, the first regions 234 are electrically isolated from the second regions 236 and from one another (e.g., by the gaps 238 of FIG. 2A or by the at least one solid dielectric material 239 of FIG. 2B) such that the interface layer 225 does not electrically short the first portions 214 to one another and does not electrically short the third portions 224 to one another. In certain implementations, at least some second regions 236 of the at least one oxide material 232 can be between at least some adjacent first regions 234 of the at least one oxide material 232 (e.g., between each adjacent pair of first regions 234). A portion of the at least one oxide material 232 (e.g., the second regions 236) can be at a periphery of the first and second substrates 210, 220. In certain implementations, the portion of the at least one oxide material 232 at the periphery substantially surrounds (e.g., encircles) the first and/or second regions 234, 236 and can be configured to hermetically seal a second portion of the at least one oxide material 232 from an ambient environment (e.g., outside the periphery). The at least one oxide material 232 can be spaced from the periphery and/or does not substantially surround (e.g., encircle) the first and/or second regions 234, 236 or hermetically seal other portions of the at least one oxide material 232 from the ambient environment.

In certain implementations, as schematically illustrated by FIG. 2C, the at least one oxide material 232 is embedded within the at least one electrically insulative second portion 216 and/or the at least one electrically insulative fourth portion 226 (e.g., in the at least one solid dielectric material 270). In certain implementations, a portion of the solid dielectric material 270 (e.g., silicon oxycarbonitride or SiOₓN_{y}C_{z}) of the first layer 212 is at a periphery of the first and second substrates 210, 220. The solid dielectric material at the periphery substantially surrounds (e.g., encircles) the at least one first region 234 and/or the at least one second region 236 and can be configured to hermetically seal the at least one first region 234 and/or the at least one second region 236 from the ambient environment (e.g., outside the periphery). In certain implementations, the first portions 214 of the first layer 212 are embedded in the solid dielectric material 270 of the second portions 216 of the first layer 212, the third portions 224 of the second layer 222 are embedded in the solid dielectric material 270 of the fourth portions 226 of the second layer 222, with the first and second regions 234, 236 of the at least one oxide material 232 between the first layer 212 and the second layer 222. In certain implementations, the at least one oxide material 232 is patterned such that the first portions 214 are electrically insulated from one another and the third portions 224 are electrically insulated from one another. In certain implementations, the at least one oxide material 232 electrically connects multiple underlying first portions 214 to one another and/or electrically connects multiple overlying third portions 224 to one another. The solid dielectric material 270 can substantially surround (e.g., encircle) the at least one oxide material 232, hermetically sealing the first and second regions 234, 236 from the ambient environment (e.g., providing a hermetic seal ring). In certain implementations, the solid dielectric material 270 (e.g., silicon oxycarbonitride or SiOₓN_{y}C_{z}) provides higher hermeticity (e.g., lower gas leak rate) than would the at least one oxide material 232.

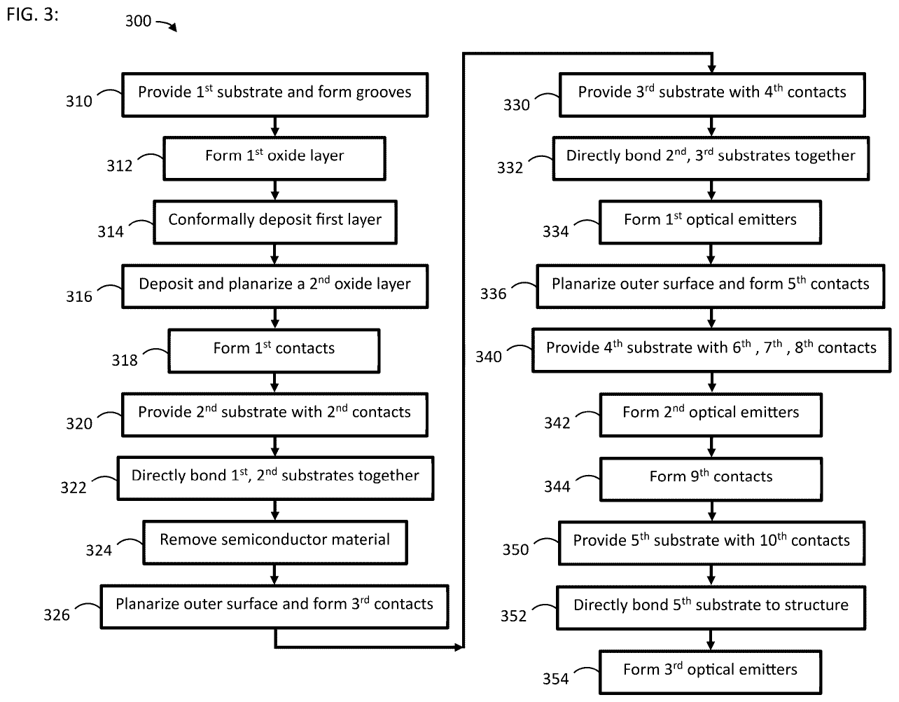

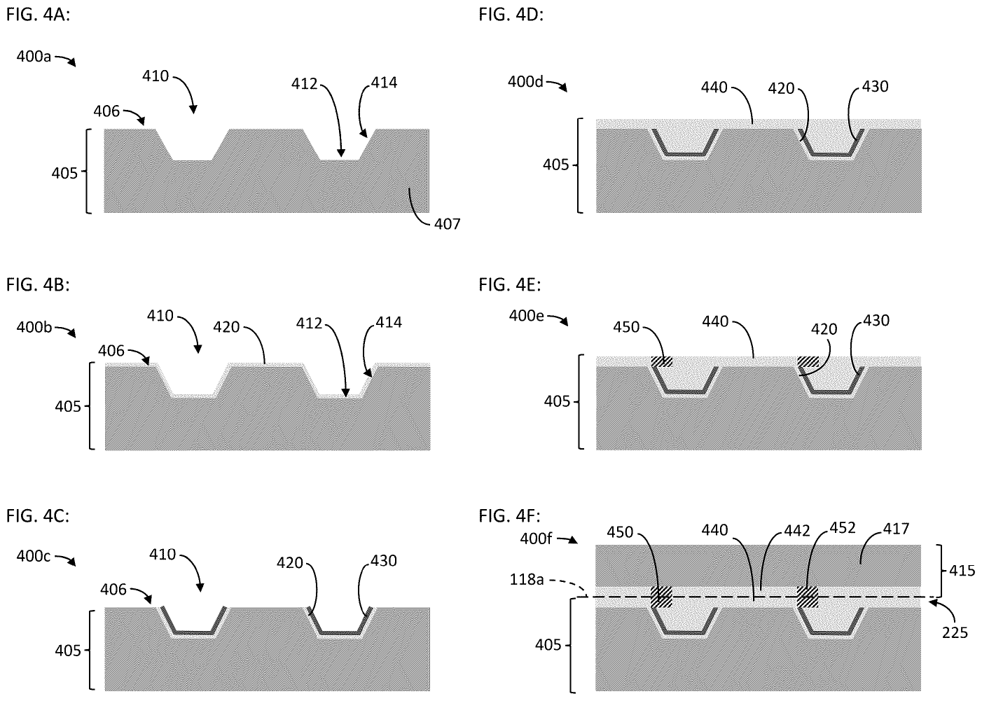

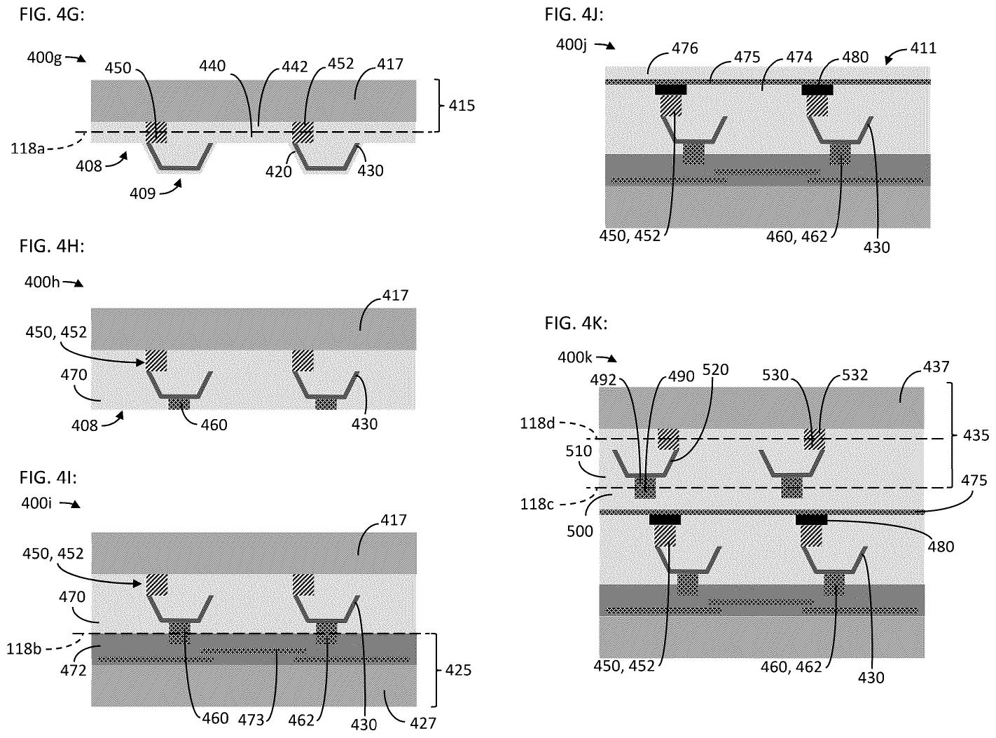

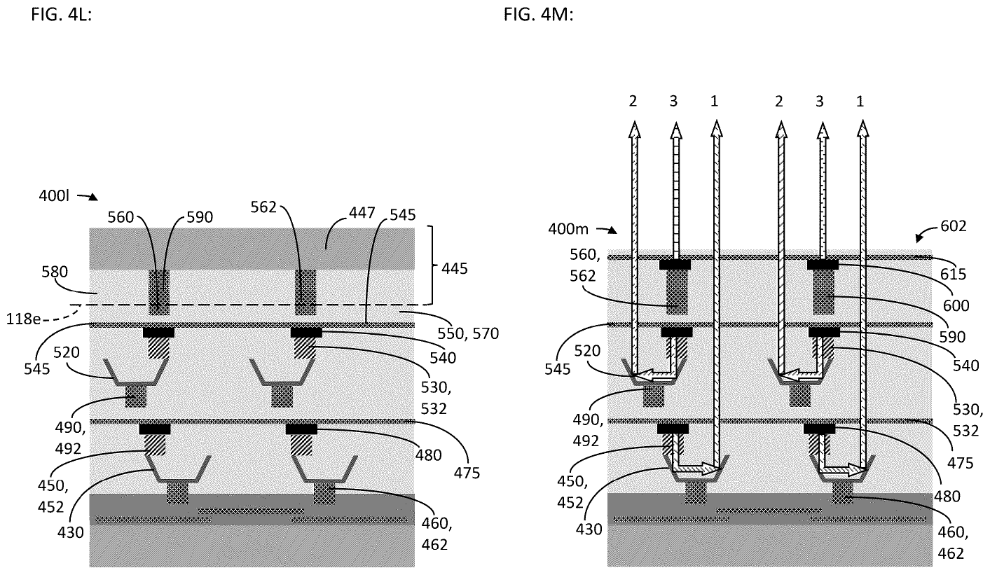

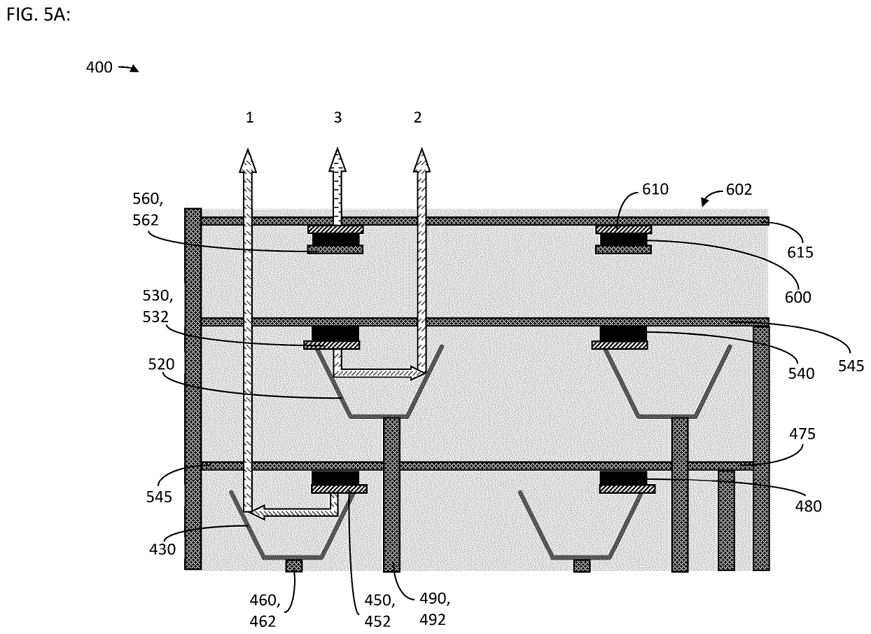

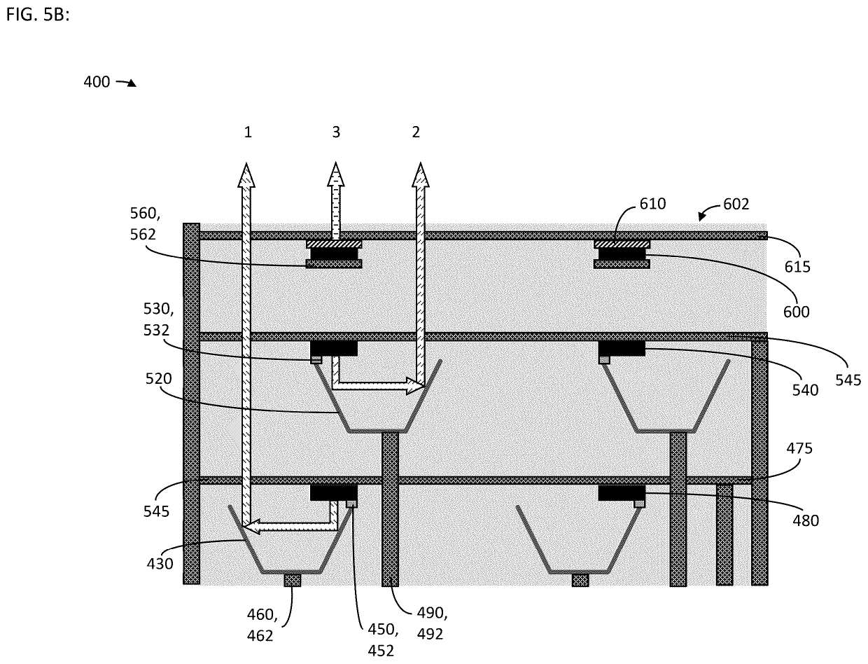

FIG. 3 is a flow diagram of an example method 300 for fabricating a structure 400 utilizing at least one oxide material 232 in accordance with certain implementations described herein. FIGS. 4A-4M schematically illustrate cross-sectional views of various example structures 400a-m that are fabricated at stages of the method 300 in accordance with certain implementations described herein. While the example method 300 is described herein by referring to the various example structures of FIGS. 4A-4M, other structures are also compatible with the example method 300 in accordance with certain implementations described herein.

In an operational block 310, the method 300 comprises providing a first substrate 405 (e.g., first substrate 210; first element 102) having an outer surface 406 and forming grooves 410 (e.g., channels; recesses) extending along the outer surface 406. For example, the first substrate 405 can comprise a first wafer 407 comprising a first semiconductor material (e.g., silicon) and forming the grooves 410 can comprise patterning the outer surface 406 and etching the grooves 410 into the outer surface 406. For example, a photoresist layer can be deposited on the outer surface 406, the photoresist layer can be patterned (e.g., using photolithographic techniques) to expose portions of the outer surface 406, and the exposed portions of the outer surface 406 can be etched away (e.g., using a plasma dry etch) to form the grooves 410. After etching, the remaining photoresist layer can be stripped off and the first substrate 405, including the outer surface 406, can be cleaned (e.g., rinsed and spin dried). In certain implementations, the grooves 410 are substantially straight (e.g., extending along the outer surface 406 in a direction substantially perpendicular to the cross-sectional plane of FIG. 4A) and are substantially parallel to one another. The width of the grooves 410 at the outer surface 406 in a direction substantially perpendicular to the grooves 410 and substantially parallel to the outer surface 406 and a distance between adjacent grooves 410 in the direction can be selected to provide a predetermined pitch of the fabricated optical elements. For example, the width of the grooves 410 can be less than 30 microns (e.g., in a range of 5 microns to 20 microns) and the distance between adjacent grooves 410 can be less than 100 microns (e.g., in a range of 20 microns to 50 microns).

As schematically illustrated by FIG. 4A, the grooves 410 can have a substantially trapezoidal cross-sectional shape with a bottom wall 412 substantially parallel to the outer surface 406 and side walls 414 that are at a non-zero angle to the bottom wall 412 (e.g., less than 90 degrees; about 45 degrees; about 55 degrees). The non-zero angle can be dependent on the crystallographic planes of the first semiconductor material in which the grooves 410 are formed. Other cross-sectional shapes of the grooves 410 are also compatible with certain implementations described herein.

In an operational block 312, the method 300 further comprises forming a first oxide layer 420 over the outer surface 406 and the grooves 410. For example, the first oxide layer 420 can comprise silicon oxide (e.g., SiO₂; SiOₓN_{y}C_{z}) and forming the first oxide layer 420 can comprise thermal oxide formation, sputtering, activated chemical vapor deposition (CVD), directional physical vapor deposition (PVD), or atomic layer deposition (ALD). As shown in FIG. 4B, the first oxide layer 420 can be conformally deposited onto the outer surface 406 and onto the bottom walls 412 and side walls 414 of the grooves 410 to have a substantially uniform thickness (e.g., less than 5 microns; about 1 micron).

In an operational block 314, the method 300 further comprises conformally depositing an electrically conductive and optically reflective first layer 430 over the first oxide layer 420 at least within the grooves 410 and removing portions of the first layer 430 and the first oxide layer 420 outside the grooves 410. For example, the first layer 430 can comprise a metal or metal alloy (e.g., comprising an atomic element selected from: Cu, Al, Cr, Ni, Au, Ag) and can have a thickness less than 1 micron (e.g., in a range of 0.1 micron to 0.5 micron). Conformally depositing the first layer 430 can comprise sputtering, activated CVD, directional PVD, or ALD. Removing the portions of the first layer 430 and the first oxide layer 420 outside the grooves 410 can comprise planarizing a top surface of the structure 400 (e.g., using chemical mechanical polishing or CMP), resulting in separate first layers 430 (e.g., electrically insulated and spaced from one another), as shown in FIG. 4C. By being conformally deposited within the grooves 410, the first layers 430 have substantially the same cross-sectional shape as do the grooves 410 (e.g., a substantially trapezoidal cross-sectional shape).

In an operational block 316, the method 300 further comprises depositing and planarizing a second oxide layer 440 over the first layer 430 within the grooves 410 and over the outer surface 406. For example, the second oxide layer 440 can comprise silicon oxide (e.g., SiO₂; SiOₓN_{y}C_{z}) and depositing the second oxide layer 440 can comprise sputtering, activated CVD, directional PVD, or ALD. Planarizing the second oxide layer 440 can comprise using CMP, resulting in the structure 400d shown in FIG. 4D. The planarized second oxide layer 440 can have a thickness less than 500 nanometers (e.g., in a range of 100 nanometers to 200 nanometers).

In an operational block 318, the method 300 further comprises forming electrically conductive and optically transparent first contacts 450 embedded within the second oxide layer 440 and in electrical communication with the first layer 430 (see, e.g., FIG. 4E). For example, the first contacts 450 can comprise at least one oxide material 232 selected from the group consisting of: indium tin oxide (ITO); zinc oxide (ZnO); indium-doped zinc oxide (IZO); tin oxide (SnO₂); fluorine-doped tin oxide (FTO). The first contacts 450 can have a thickness less than 500 nanometers (e.g., in a range of 100 nanometers to 200 nanometers; substantially equal to the thickness of the second oxide layer 440, as shown in FIG. 4D). In certain implementations, the resistivity of the first contacts 450 is in a range less than 500×10⁻⁶ Ω-cm (e.g., 200×10⁻⁶ Ω-cm to 40×10⁻⁶ Ω-cm; 500×10⁻⁶ Ω-cm to 20×10⁻⁶ Ω-cm; in a range less than 120×10⁻⁶ Ω-cm). In certain implementations, the optical transmission of the first contacts 450 within the wavelength range of interest is greater than 40% (e.g., greater than 60%; greater than 80%). In certain implementations, forming the first contacts 450 further comprises planarization of the outer surfaces of the second oxide layer 440 and the first contacts 450.

The outer surfaces of the first contacts 450 can be recessed (e.g., by less than 10 nanometers) relative to the outer surfaces of the second oxide layer 440. For example, recesses can be formed in the second oxide layer 440 using photolithographic techniques, the recesses extending through the second oxide layer 440 to a top portion of the first layer 430 and the at least one oxide material 232 (e.g., ITO; SnO₂) can be deposited over the second oxide layer 440 substantially filling the recesses with the at least one oxide material 232. For example, depositing the at least one oxide material 232 can comprise sputtering, activated CVD, directional PVD, or ALD to a thickness on the order of microns. After depositing the at least one oxide material 232, the at least one oxide material 232 can be planarized (e.g., using CMP) to remove the portions of the at least one oxide material 232 outside the recesses, thereby forming the first contacts 450 over and in electrical communication with the first layer 430. The outer surface of the first contacts 450 can be recessed relative to the outer surface of the adjacent and surrounding second oxide layer 440 (e.g., in a range of 2 nanometers to 8 nanometers) to account for the differing coefficients of thermal expansion (CTE) of the at least one oxide material 232 and the second oxide layer 440 (e.g., differing amounts of thermal expansion in a direction perpendicular to the top surfaces during subsequent annealing). For example, the CTE of ITO is about 5.8×10⁻⁶/K to 9×10⁻⁶/K while the CTE of silicon oxide is about 0.5×10⁻⁶/K. For comparison, the CTE of Cu is about 16.7×10⁻⁶/K. The thickness of the ITO can be selected to be thicker and the magnitude of the recess between the ITO and the neighboring silicon oxide can be more tightly controlled to account for the smaller CTE differential for ITO/SiO₂. After planarization, the outer surfaces of the first contact 450 and the second oxide layer 440 can be cleaned (e.g., rinsed and spin dried) sufficiently for subsequent directly bonding.

In an operational block 320, the method 300 further comprises providing a second substrate 415 (e.g., second substrate 220; second element 104) comprising a third oxide layer 442 at an outer surface of the second substrate 415 and second contacts 452 embedded in the third oxide layer 442. For example, the second substrate 415 can comprise a second wafer 417 comprising a second semiconductor material (e.g., Si; GaAs; GaN; GaP; InP, AlGaAs, etc.). The second and third oxide layers 440, 442 can comprise the same material as one another, or can comprise different materials (e.g., materials having different elemental constituents and/or different stoichiometries) from one another. The second contacts 452 can comprise at least one electrically conductive oxide material 232 selected from the group consisting of: indium tin oxide (ITO); zinc oxide (ZnO); indium-doped zinc oxide (IZO); tin oxide (SnO₂). The first and second contacts 450, 452 can comprise the same material as one another, or can comprise different materials (e.g., materials having different elemental constituents and/or different stoichiometries) from one another. The third oxide layer 442 and the second contacts 452 can be formed in the same manner as the forming of the second oxide layer 440 and the first contacts 450 (e.g., as described herein with regard to operational block 318).

In an operational block 322, the method 300 further comprises directly bonding the second substrate 415 to the first substrate 405 (e.g., directly bonding the third oxide layer 442 to the second oxide layer 440 and directly bonding the second contacts 452 to the first contacts 450; without an intervening adhesive; at room temperature; at temperatures below 35° C.). For example, the first substrate 405 and the second substrate 415 can be contacted with one another with the first and second contacts 450, 452 therebetween. Examples of such bonding are disclosed in U.S. patent application Ser. No. 18/391,173, filed Dec. 20, 2023, the entire contents of which is incorporated by reference herein in its entirety for providing examples of bonding contacts comprising electrically conductive and optically transparent layers to one another. As shown in FIG. 4F, the resulting structure 400f has an interface layer 225 comprising the second and third oxide layers 440, 442, the first and second contacts 450, 452 and a bond interface 118a (denoted by a dashed line).

In certain implementations, at least one of the first and second substrates 405, 415 is not planarized after patterning the first and second contacts 450, 452 and prior to the directly bonding. Omitting one or both of these steps can simplify the direct bonding process flow and reduce manufacturing costs. Without being limited by theory, the material properties of the first and second contacts 450, 452 can form direct bonds after a low temperature anneal without requiring planarization and/or activation. As explained herein, annealing can cause expansion of the first and second contacts 450, 452, and/or can cause grain growth to facilitate electrical connection between the first and second contacts 450, 452. In certain other implementations, one or both of the first and second substrates 405, 415 can be planarized and/or activated after patterning the first and second contacts 450, 452 and before direct bonding.

In certain implementations, after a room temperature bonding of the first and second substrates 405, 415 to one another, the structure 400f is annealed at a temperature higher than room temperature (e.g., in a range of 120° C. to 500° C.; in a range of 120° C. to 150° C.; in a range of 150° C. to 350° C.) for an annealing time in a range of 10 minutes to more than 2 hours (e.g., higher annealing temperatures using shorter annealing times). The annealing ambient can comprise at least one of: nitrogen, forming gas, hydrogen plasma, vacuum, or other predetermined ambient. The annealing chamber can comprise one or more ovens (e.g., rapid thermal anneal (RTA) ovens; microwave ovens; ovens for processing semiconductor wafers, flat panels, etc.). The annealing process can cause the first and second contacts 450, 452 to expand to increase contact pressure at the bond interface 118a. Annealing can additionally or alternatively cause grain growth across the bond interface 118a such that the grains can migrate at least partially across the bond interface 118a. After the annealing process, the opposing second and third oxide layers 440, 442 can be permanently bonded to one another, with a bond energy of the bond interface 118a of at least 1000 mJm⁻² (e.g., higher than 2000 mJm⁻²). Similarly, the opposing first and second contacts 450, 452 can be mechanically bonded and electrically coupled to one another. The alignment between the first and second contacts 450, 452 can be sufficient to provide substantial electrical contact between the first and second contacts 450, 452 (e.g., the alignment can be less than perfect).

In certain other implementations, the first and second substrates 405, 415 are annealed at a first temperature in a suitable oven, the first temperature sufficiently high to enlarge the grain structure of the first and second contacts 450, 452 before the bonding operation. The outer surfaces of the first and second contacts 450, 452 with large grains can then be cleaned and bonded. In certain such implementations, at least one of the cleaned outer surfaces of the first and second contacts 450, 452 and the second and third oxide layers 440, 442 can be activated (e.g., exposed to a plasma and/or chemical etchants) before the bonding operation, while in certain other implementations, at least one of the cleaned outer surfaces of the first and second contacts 450, 452 and the second and third oxide layers 440, 442 is not activated before the bonding operation. The bonded first and second substrates 405, 415 can be annealed at a second temperature that can be substantially equal to or greater than the first temperature. In certain implementations, before planarization of the outer surfaces of the second and third oxide layers 440, 442 and the first and second contacts 450, 452, the first and second substrates 405, 415 can be annealed at a first temperature (e.g., lower than 250° C.).

In an operational block 324, the method 300 further comprises removing the first semiconductor material (e.g., silicon) below the first oxide layer 420 of the first substrate 405 from the structure 400f, resulting in the structure 400g of FIG. 4G. For example, the first semiconductor material can be removed by wet or dry etching. As a result, a second outer surface 408 of the structure 400g has a plurality of protrusions 409, each comprising a corresponding first layer 430 covered by the first oxide layer 420, as shown in FIG. 4G.

In an operational block 326, the method 300 further comprises planarizing the second outer surface 408 and forming electrically conductive third contacts 460, each third contact 460 in electrical communication with a corresponding first layer 430, as shown in FIG. 4H. For example, an oxide material 470 (e.g., the same material as the first oxide layer 420 and/or the second oxide layer 440) can be deposited over the second outer surface 408 and covering the protrusions 409. Recesses can be etched into the oxide material 470, an electrically conductive material (e.g., Cu; Al; Cr; Ni; Au; Ag; or other metals and/or alloys) can be deposited over the oxide material 470 and filling the recesses, and the second outer surface 408 of the structure 400h can be polished, resulting in the structure 400h shown in FIG. 4H.

In an operational block 330, the method 300 further comprises providing a third substrate 425 comprising an oxide material 472 at an outer surface of the third substrate 230 and fourth contacts 462 embedded in the oxide material 472. For example, the third substrate 425 can comprise a third wafer 427 (e.g., a CMOS driver wafer) comprising semiconductor material (e.g., Si; GaAs; GaN; GaP; GaAlAs). The oxide materials 470, 472 can comprise the same material as one another, or can comprise different materials (e.g., materials having different elemental constituents and/or different stoichiometries) from one another. The fourth contacts 462 can comprise an electrically conductive material (e.g., Cu; Al; Cr; Ni; Au; Ag; or other metals and/or alloys). The third and fourth contacts 460, 462 can comprise the same material as one another, or can comprise different materials (e.g., materials having different elemental constituents and/or different stoichiometries) from one another. The third substrate 425 can further comprise electrically conductive traces 473 embedded within the oxide material 472. The materials of the fourth contacts 462, oxide material 472, and traces 473 of the third substrate 425 can be substantially opaque.

In an operational block 332, the method 300 further comprises directly bonding the third substrate 425 to the second substrate 415 (e.g., directly bonding the oxide materials 470, 472 to one another and directly bonding the fourth contacts 462 to the third contacts 460; without an intervening adhesive; at room temperature; at temperatures below 35° C.). For example, the third substrate 425 and the second substrate 415 can be contacted with one another with the third and fourth contacts 460, 462 therebetween. In certain implementations, the third and fourth contacts 460, 462 are directly bonded to one another. For example, a hybrid bonding technique can be used to provide conductor-to-conductor direct bonds along the bond interface 118b (denoted by a dashed line) that includes covalently direct bonded non-conductive-to-non-conductive (e.g., dielectric-to-dielectric) surfaces, prepared as described herein. In typical implementations that employ metal conductive features, the conductor-to-conductor (e.g., third contacts 460 to fourth contacts 462) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. In hybrid bonding implementations described herein, the electrically conductive third and fourth contacts 460, 462 and the nonconductive oxide materials 470, 472 are prepared for direct bonding, such as by the planarization, activation and/or termination treatments described herein. Thus, the bonding interface 118b prepared for direct bonding includes both conductive and nonconductive features, and the resulting structure 400i is shown in FIG. 4I.

In an operational block 334, the method 300 further comprises forming first optical emitters 480 (e.g., LEDs) configured to emit light having a first color (e.g., red, green, or blue). The first optical emitters 480 are configured to emit the light towards the first layers 430 and are in electrical communication with the first and second contacts 450, 452. For example, a portion of the second wafer 417 (e.g., GaAlAs) of the second substrate 415 can be removed (e.g., etched away) and a remaining portion of the second wafer 417 of the second substrate 415 in electrical communication with the first and second contacts 450, 452 can be doped to provide the first optical emitters 480. The third wafer 427 can comprise a driver element comprising driver circuitry configured to control operation of the at least one first optical emitter 480. An outer surface of the second substrate 415 can be planarized (e.g., by depositing nonconductive oxide material 474 on the first optical emitters 480 and the outer surface of the nonconductive oxide material 470, and polished using CMP). Electrically conductive traces 475 can be formed (e.g., deposited), and nonconductive and optically transparent oxide material 476 can be deposited over the traces 475 and polished using CMP. The traces 475 can be optically opaque or can be optically transparent, and can form a two-dimensional grid in a plane substantially perpendicular to the cross-sectional plane of FIG. 4J. The oxide materials 474, 476 and the traces 475 embedded in the oxide materials 474, 476 can be an interconnect layer. The traces 475 and the first and second contacts 450, 452 (e.g., via the first layer 430 and the third and fourth contacts 460, 462) can provide electrical connections to apply a voltage difference across the first optical emitters 480.

In an operational block 336, the method 300 further comprises planarizing a third outer surface 411 of the structure 400j and forming electrically conductive fifth contacts 490 at the third outer surface 411. For example, a nonconductive and optically transparent oxide material 500 (e.g., the same material as the nonconductive and optically transparent oxide material 476) can be deposited over the third outer surface 411. Recesses can be etched into the oxide material 500, an electrically conductive and optically opaque material (e.g., Cu; Al; Cr; Ni; Au; Ag; or other metals and/or alloys) can be deposited over the oxide material 500 and filling the recesses, and the excess electrically conductive and optically opaque material outside the recesses can be removed from the third outer surface 411 (e.g., via CMP).

In an operational block 340, the method 300 further comprises providing a fourth substrate 435 comprising a nonconductive and optically transparent material 510, electrically conductive and optically reflective second layers 520, and electrically conductive and optically opaque sixth contacts 492 in electrical communication with the second layers 520. The fourth substrate 435 further comprises electrically conductive and optically transparent seventh contacts 530 in electrical communication with the second layers 520, electrically conductive and optically transparent eighth contacts 532 in electrical communication with the seventh contacts 530, and a fourth wafer 437 in electrical communication with the eighth contacts 532. In certain implementations, the fourth substrate 435 is similar to the structure 400h, and providing the fourth substrate 435 can comprise fabrication steps similar to those described herein with regard to providing the structure 400h (e.g., operational blocks 310, 312, 314, 316, 318, 320, 322, 324, 326). In certain implementations, the second layers 520 extend in a substantially straight direction that is substantially perpendicular to the cross-sectional plane of FIG. 4K) and are substantially parallel to one another. In certain implementations, as shown in the cross-sectional view of FIG. 4K, the second layers 520 extend in a direction that is substantially parallel to the direction along which the first layers 430 extend, while in certain other implementations, the second layers 520 extend in a direction that is substantially perpendicular to the direction along which the first layers 430 extend.

In certain implementations, the fifth and sixth contacts 490, 492 are directly bonded to one another. For example, a hybrid bonding technique can be used to provide conductor-to-conductor direct bonds along the bond interface 118c (denoted by a dashed line) that includes covalently direct bonded non-conductive-to-non-conductive (e.g., dielectric-to-dielectric) surfaces, prepared as described herein. In typical implementations that employ metal conductive features, the conductor-to-conductor (e.g., fifth contacts 490 to sixth contacts 492) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. In hybrid bonding implementations described herein, the electrically conductive fifth and sixth contacts 490, 492 and the nonconductive oxide materials 500, 510 are prepared for direct bonding, such as by the planarization, activation and/or termination treatments described herein. Thus, the bonding interface 118c prepared for direct bonding includes both conductive and nonconductive features, as shown in FIG. 4K.

In certain implementations, the fourth substrate 435 is formed by directly bonding two substrates to one another with the seventh and eighth contacts 530, 532 therebetween (e.g., directly bonding the eighth contacts 532 to the seventh contacts 530; without an intervening adhesive; at room temperature; at temperatures below 35° C.). Examples of such bonding are disclosed in U.S. patent application Ser. No. 18/391,173, filed Dec. 20, 2023, the entire contents of which is incorporated by reference herein in its entirety for providing examples of bonding contacts comprising electrically conductive and optically transparent layers to one another. As shown in FIG. 4K, the resulting structure 400k has a bond interface 118d (denoted by a dashed line).

In an operational block 342, the method 300 further comprises forming second optical emitters 540 (e.g., LEDs) configured to emit light having a second color (e.g., red, green, or blue), the second color different from the first color of the first optical emitters 480. The second optical emitters 540 are configured to emit the light towards the second layers 520 and are in electrical communication with the seventh and eighth contacts 530, 532. For example, a portion of the fourth wafer 437 (e.g., GaP) of the fourth substrate 435 can be removed (e.g., etched away) and a remaining portion of the fourth wafer 437 of the fourth substrate 435 in electrical communication with the seventh and eighth contacts 530, 532 can be doped to provide the second optical emitters 540. An outer surface of the fourth substrate 435 can be planarized (e.g., by depositing nonconductive oxide material on the second optical emitters 540 and the outer surface of the nonconductive oxide material 510, and then polishing using CMP). Electrically conductive traces 545 can be formed (e.g., deposited), and nonconductive and optically transparent oxide material 550 can be deposited over the traces 545 and polished using CMP. The traces 545 can be optically opaque or can be optically transparent, and can form a two-dimensional grid in a plane substantially perpendicular to the cross-sectional plane of FIG. 4L. The traces 545 and the seventh and eighth contacts 530, 532 (e.g., via the second layers 520 and the fifth and sixth contacts 490, 492) can provide electrical connections to apply a voltage difference across the second optical emitters 540.

In an operational block 344, the method 300 further comprises forming electrically conductive ninth contacts 560 at a fourth outer surface of the structure 400. For example, a nonconductive and optically transparent oxide material 570 (e.g., the same material as the nonconductive and optically transparent oxide material 550 over the traces 545) can be deposited and recesses can be etched into the oxide material 570, an electrically conductive and optically opaque material (e.g., Cu; Al; Cr; Ni; Au; Ag; or other metals and/or alloys) can be deposited over the oxide material 570 and filling the recesses, and the excess electrically conductive and optically opaque material outside the recesses can be removed from the outer surface (e.g., via CMP).

In an operational block 350, the method 300 further comprises providing a fifth substrate 445 comprising a nonconductive and optically transparent material 580 and electrically conductive and optically opaque vias 590 extending through the material 580 and comprising tenth contacts 562 at a bottom outer surface of the fifth substrate 445. The fifth substrate 445 further comprises a fifth wafer 447 in electrical communication with the vias 590.

In an operational block 352, the method 300 further comprises directly bonding the fifth substrate 445 to the structure 400 (e.g., directly bonding the oxide materials 570, 580 to one another and directly bonding the tenth contacts 562 to the ninth contacts 560; without an intervening adhesive; at room temperature; at temperatures below 35° C.), forming the structure 4401 shown in FIG. 4L. For example, the oxide materials 570, 580 can be contacted with one another and the ninth and tenth contacts 560, 562 can be contacted with one another. In certain implementations, the ninth and tenth contacts 560, 562 are directly bonded to one another. For example, a hybrid bonding technique can be used to provide conductor-to-conductor direct bonds along the bond interface 118e (denoted by a dashed line) that includes covalently direct bonded non-conductive-to-non-conductive (e.g., dielectric-to-dielectric) surfaces, prepared as described herein. In typical implementations that employ metal conductive features, the conductor-to-conductor (e.g., ninth contacts 560 to tenth contacts 562) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. In hybrid bonding implementations described herein, the electrically conductive ninth and tenth contacts 560, 562 and the nonconductive oxide materials 570, 580 are prepared for direct bonding, such as by the planarization, activation and/or termination treatments described herein. Thus, the bonding interface 118e prepared for direct bonding includes both conductive and nonconductive features.

In an operational block 354, the method 300 further comprises forming third optical emitters 600 (e.g., LEDs) configured to emit light having a third color (e.g., red, green, or blue), the third color different from the first color of the first optical emitters 480 and the second color of the second optical emitters 540. The third optical emitters 600 are configured to emit the light towards and through an outer surface 602 of the structure 400 (e.g., away from the underlying first and second optical emitters 480, 540) and are in electrical communication with the vias 590. For example, a portion of the fifth wafer 447 (e.g., GaN on sapphire) of the fifth substrate 445 can be removed (e.g., etched away) and a remaining portion of the fifth wafer 447 of the fifth substrate 445 in electrical communication with the vias 590 can be doped to provide the third optical emitters 600. The outer surface 602 of the structure 400 can be planarized (e.g., by depositing nonconductive oxide material on the third optical emitters 600 and the outer surface of the nonconductive oxide material 580, and then polishing using CMP). Electrically conductive traces 615 can be formed (e.g., deposited), and nonconductive and optically transparent oxide material 620 can be deposited over the traces 615 and polished using CMP. The traces 615 can be optically opaque or can be optically transparent, and can form a two-dimensional grid in a plane substantially perpendicular to the cross-sectional plane of FIG. 4M. The traces 615 and the vias 590 can provide electrical connections to apply a voltage difference across the third optical emitters 600.

As schematically illustrated in the cross-sectional view of FIG. 4M, the third optical emitters 600 are stacked over the second optical emitters 540, and the second optical emitters 540 are stacked over the first optical emitters 480, defining a stack line along which the first, second, and third optical emitters 480, 540, 600 are arranged. In certain implementations (see, e.g., FIG. 4M), the stack line is substantially perpendicular to the outer surface 602.

The light emitted from the first optical emitters 480 (e.g., the first light, denoted by the arrows labeled “1”) propagates through the optically transparent first and second contacts 450, 452, impinges and is reflected from a first portion of the optically reflective first layers 430, impinges and is reflected from a second portion of the first layers 430, and propagates from the second portion of the first layers 430 through the intervening optically transparent oxide materials, and is emitted through the outer surface 602. In this way, the first light is initially emitted from the first optical emitters 480 in a downward direction along the stack line and is twice reflected from the first layers 430 (e.g., first mirror structure) to be deflected to propagate in an upward direction (e.g., substantially different from the downward direction; substantially opposite to the downward direction) along a line displaced from and substantially parallel to the stack line.

Similarly, the light emitted from the second optical emitters 540 (e.g., the second light, denoted by the arrows labeled “2”) propagates through the optically transparent seventh and eighth contacts 530, 532, impinges and is reflected from a first portion of the optically reflective second layers 520, impinges and is reflected from a second portion of the second layers 520, and propagates from the second portion of the second layers 520 through the intervening optically transparent oxide materials, and is emitted through the outer surface 602. In this way, the second light is initially emitted from the second optical emitters 540 in a downward direction along the stack line and is twice reflected from the second layers 520 (e.g., second mirror structure) to be deflected to propagate in an upward direction (e.g., substantially different from the downward direction; substantially opposite to the downward direction) along a line displaced from and substantially parallel to the stack line. As seen in FIG. 4M, the second light is emitted substantially parallel to the first light and with a displacement from the stack line that is opposite to the displacement of the first light from the stack line (e.g., on opposite sides of the stack line). In certain other implementations having other shapes of the first layers 430 and/or second layers 520, the first light and/or the second light can be reflected more than twice by the corresponding first layers 430 and/or second layers 520.

Unlike the first and second light, the light emitted from the third optical emitters 600 (e.g., third light, denoted by the arrows labeled “3”) propagates initially in an upward direction and reaches the outer surface 602 without being deflected by reflective layers. The third light propagates substantially along the direction of the stack line (e.g., colinear with the stack line; is not displaced from the stack line) such that the third light is emitted from the outer surface 602 with a first displacement from the first light and a second displacement from the second light (e.g., the magnitudes of the first and second displacements substantially equal to one another).

FIGS. 5A and 5B schematically illustrate side views of two example structures 400 in accordance with certain implementations described herein. FIG. 5A is similar to FIG. 4M and shows that, in certain implementations, the first light from the first optical emitters 480 propagates through the optically transparent first and second contacts 450, 452 which also provide electrical connection to a first side of the first optical emitters 480 via the first layers 430 and other electrical conduits. In addition, the second light from the second optical emitters 540 propagates through the optically transparent seventh and eighth contacts 530, 532 which also provide electrical connection to a first side of the second optical emitters 540 via the second layers 520 and other electrical conduits. As shown in FIG. 5A, the third light from the third optical emitters 600 can propagate through an electrically conductive and optically transparent material 610 (e.g., ITO) that provide electrical connection between the third optical emitters 600 and the traces 615.

As schematically illustrated in FIG. 5B, the first and second contacts 450, 452 are optically opaque and do not extend across the full side of the first optical emitters 480 such that the first light does not propagate therethrough, and/or the seventh and eighth contacts 530, 532 are optically opaque and do not extend across the full side of the second optical emitters 540 such that the second light does not propagate therethrough. For example, depending on the pitch of the stacks of the first, second, and third optical emitters 480, 540, 600 (e.g., the distances between the stacks), the first and/or second optical emitters 480, 540 can be hybrid bonded (e.g., with Cu contacts instead of ITO). Such contacts 450, 452, 530, 532 can have sufficiently small widths and can be positioned at edges of the corresponding first and second optical emitters 480, 540 such that the first light and the second light do not experience substantial absorption loss. Although only one pair of contacts 450, 452 are shown per optical emitter 480, 540, multiple contacts (e.g., for each electrode) can be provided in different shapes and sizes.

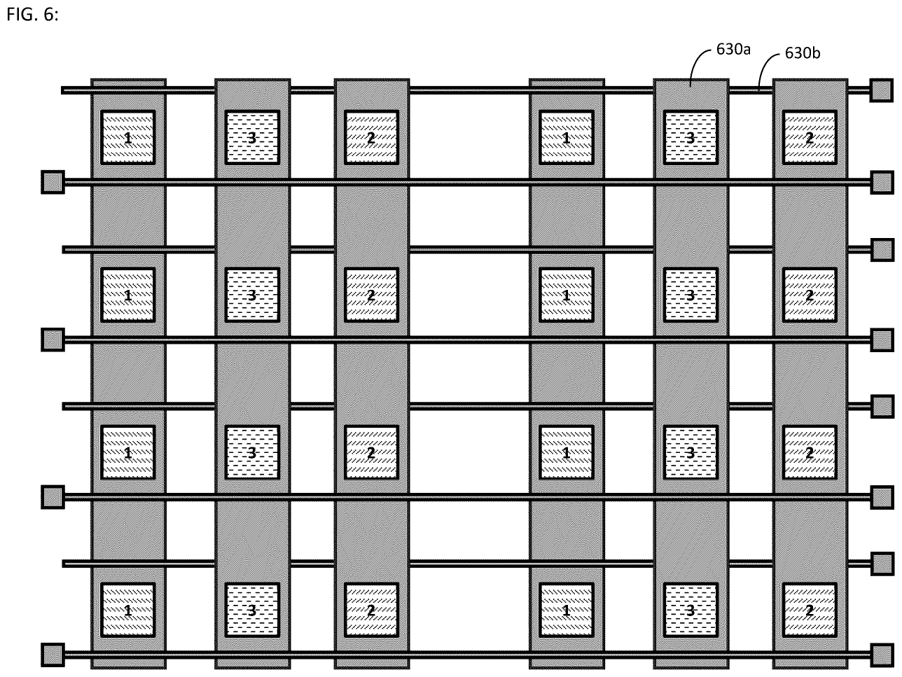

FIG. 6 schematically illustrates a top view of the outer surface 602 through which the first, second, and third light are transmitted in accordance with certain implementations described herein. The first, second, and third optical emitters 480, 540, 600 are stacked along the stack lines beneath the locations where the third light is emitted from the outer surface 602 (denoted by the squares labeled “3”). The first reflective layers 430 twice reflect the first light (denoted by the squares labeled “1”) from the first optical emitters 480 to have a first displacement relative to the stack line and the second reflective layers 520 twice reflect the second light (denoted by the squares labeled “2”) from the second optical emitters 540 to have a second displacement relative to the stack line, the first and second displacements opposite to one another (e.g., and having substantially the same magnitude as one another). FIG. 6 also shows various reflective layer portions 630a (e.g., portions of reflective layers 430, 520) and electrically conductive Cu lines 630b (e.g., the traces 475, 545, 615) that can be at various different depths from the outer surface 602 and configured to provide electrical voltage to the first, second, and third optical emitters 480, 540, 600. The reflected first light propagates along a first optical channel through the outer surface 602 and the reflected second light propagates along a second optical channel through the outer surface 602, the first and second optical channels laterally spaced from one another along a direction transverse to the first direction. Each set of three laterally spaced rays of first, second, and third light emitted from a given stack through the outer surface 602 can be considered to be a three color pixel.

Although commonly used terms are used to describe the systems and methods of certain implementations for ease of understanding, these terms are used herein to be interpreted fairly. Although various aspects of the disclosure are described with regard to illustrative examples and implementations, the disclosed examples and implementations should not be construed as limiting. Conditional language, such as, among others, “can,” “could,” “might,” or “may,” unless specifically stated otherwise, or otherwise understood within the context as used, is generally intended to convey that certain implementations include, while other implementations do not include, certain features, elements and/or steps. Thus, such conditional language is not generally intended to imply that features, elements and/or steps are in any way required for one or more implementations or that one or more implementations necessarily include logic for deciding, with or without user input or prompting, whether these features, elements and/or steps are included or are to be performed in any particular implementation. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

It is to be appreciated that the implementations disclosed herein are not mutually exclusive and may be combined with one another in various arrangements. In addition, although the disclosed methods and apparatuses have largely been described in the context of direct bonding processes, various implementations described herein can be incorporated in a variety of other suitable devices, methods, and contexts.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within ±10% of, within ±5% of, within ±2% of, within ±1% of, or within ±0.1% of the stated amount. As another example, the terms “generally parallel” and “substantially parallel” refer to a value, amount, or characteristic that departs from exactly parallel by ±10 degrees, by ±5 degrees, by ±2 degrees, by ±1 degree, or by ±0.1 degree, and the terms “generally perpendicular” and “substantially perpendicular” refer to a value, amount, or characteristic that departs from exactly perpendicular by ±10 degrees, by ±5 degrees, by ±2 degrees, by ±1 degree, or by ±0.1 degree. The ranges disclosed herein also encompass any and all overlap, sub-ranges, and combinations thereof. Language such as “up to,” “at least,” “greater than,” less than,” “between,” and the like includes the number recited. As used herein, the meaning of “a,” “an,” and “said” includes plural reference unless the context clearly dictates otherwise. Also, as used in the description herein, the meaning of “in” includes “into” and “on,” unless the context clearly dictates otherwise.

While the methods and systems are discussed herein in terms of elements labeled by ordinal adjectives (e.g., first, second, etc.), the ordinal adjective are used merely as labels to distinguish one element from another (e.g., one substrate from another or one surface layer from one another), and the ordinal adjective is not used to denote an order of these elements or of their use.

The disclosure described and claimed herein is not to be limited in scope by the specific example implementations herein disclosed, since these implementations are intended as illustrations, and not limitations, of several aspects of the disclosure. Any equivalent implementations are intended to be within the scope of this disclosure. Indeed, various modifications of the disclosure in form and detail, in addition to those shown and described herein, will become apparent to those skilled in the art from the foregoing description. Such modifications are also intended to fall within the scope of the claims. The breadth and scope of the disclosure should not be limited by any of the example implementations disclosed herein, but should be defined only in accordance with the claims and their equivalents.

The invention claimed is:

1. A structure comprising:
an outer surface;
at least one first optical emitter at or below the outer surface, the at least one first optical emitter to emit a first light in a first direction away from the outer surface;
at least one optically transparent first layer beneath the at least one first optical emitter; and
at least one electrically conductive and optically reflective second layer in electrical communication with the at least one first optical emitter, the at least one electrically conductive and optically reflective second layer to receive at least some of the first light propagating in the first direction from the at least one first optical emitter through the at least one optically transparent first layer and to at least twice reflect at least a portion of the received first light to propagate in a second direction towards and through the outer surface, the second direction substantially different from the first direction.

2. The structure of claim 1, wherein the at least one optically transparent first layer comprises at least one electrically conductive oxide material.

3. (canceled)

4. The structure of claim 2, wherein the at least one electrically conductive oxide material comprises a first electrically conductive oxide layer and a second electrically conductive oxide layer, the first electrically conductive oxide layer directly bonded to the second electrically conductive oxide layer.

5. The structure of claim 1, wherein the at least one optically transparent first layer comprises at least one electrically insulative material.

6. (canceled)

7. The structure of claim 5, wherein the at least one electrically insulative material comprises a first electrically insulative layer and a second electrically insulative layer, the first electrically insulative layer directly bonded to the second electrically insulative layer.

8. The structure of claim 1, wherein the at least one electrically conductive and optically reflective second layer comprises a metal or metal alloy comprising an atomic element selected from the group consisting of: copper, aluminum, chromium, nickel, gold, and silver.

9. The structure of claim 8, wherein the at least one electrically conductive and optically reflective second layer has a substantially trapezoidal cross-sectional shape in a plane substantially perpendicular to the outer surface, and comprises a first portion and a second portion, wherein:
the first portion receives at least some of the first light propagating in the first direction and reflects at least some of the received first light to propagate towards the second portion; and
the second portion receives and reflects at least some of the first light reflected from the first portion to propagate in the second direction, the second direction substantially opposite to the first direction.

10. The structure of claim 1, further comprising:
at least one second optical emitter at or below the outer surface, the at least one second optical emitter to emit a second light in a third direction away from the outer surface;
at least one optically transparent third layer beneath the at least one second optical emitter; and
at least one electrically conductive and optically reflective fourth layer in electrical communication with the at least one second optical emitter, the at least one electrically conductive and optically reflective fourth layer to receive at least some of the second light propagating in the third direction from the at least one second optical emitter through the at least one optically transparent third layer and to at least twice reflect at least a portion of the received second light to propagate in a fourth direction towards and through the outer surface, the fourth direction substantially different from the third direction.

11. The structure of claim 10, wherein the at least one first optical emitter is below and aligned with the at least one second optical emitter along a stack line substantially perpendicular to the outer surface.

12. The structure of claim 11, wherein the at least twice reflected first light propagates along a first line displaced from and substantially parallel to the stack line and the at least twice reflected second light propagates along a second line displaced from and substantially parallel to the stack line, the first line and the second line on opposite sides of the stack line.

13. The structure of claim 10, wherein the at least one optically transparent third layer comprises at least one electrically conductive oxide material.

14. (canceled)

15. The structure of claim 13, wherein the at least one electrically conductive oxide material comprises a first electrically conductive oxide layer and a second electrically conductive oxide layer, the first electrically conductive oxide layer directly bonded to the second electrically conductive oxide layer.

16. The structure of claim 10, wherein the at least one optically transparent third layer comprises at least one electrically insulative material.

17. (canceled)

18. The structure of claim 16, wherein the at least one electrically insulative material comprises a first electrically insulative layer and a second electrically insulative layer, the first electrically insulative layer directly bonded to the second electrically insulative layer.

19. The structure of claim 10, wherein the at least one electrically conductive and optically reflective fourth layer comprises a metal or metal alloy comprising an atomic element selected from the group consisting of: copper, aluminum, chromium, nickel, gold, and silver.

20. The structure of claim 19, wherein the at least one electrically conductive and optically reflective fourth layer has a substantially trapezoidal cross-sectional shape in a plane substantially perpendicular to the outer surface, and comprises a first portion and a second portion, wherein:
the first portion receives at least some of the second light propagating in the third direction and to reflect at least some of the received second light to propagate towards the second portion and
the second portion receives and reflects at least some of the second light reflected from the first portion to propagate in the fourth direction, the fourth direction substantially opposite to the third direction.

21. The structure of claim 10, further comprising at least one third optical emitter at or below the outer surface, the at least one third optical emitter to emit a third light in a fifth direction through the outer surface.

22. The structure of claim 21, wherein the third light reaches the outer surface without being deflected by reflective layers.

23. The structure of claim 21, wherein the at least one third optical emitter is above and aligned with the at least one first optical emitter and the at least one second optical emitter along a stack line substantially perpendicular to the outer surface.

24. The structure of claim 23, wherein the third light propagates along a third line substantially colinear with the stack line, the third line having a first displacement from the first light propagating through the outer surface and having a second displacement from the second light propagating through the outer surface.

25. The structure of claim 24, wherein the first and second displacements have magnitudes that are substantially equal to one another and are on opposite sides of the stack line from one another.

26.-65. (canceled)
